(19) United States
(12) Patent Application Publication
(10) Pub. No.: US 2025/0072296 A1
(43) Pub. Date: Feb. 27, 2025

(54) HALL ELEMENT AND MANUFACTURING METHOD THEREOF, AND SEMICONDUCTOR DEVICE

(71) Applicant: ROHM CO., LTD., Kyoto (JP)

(72) Inventors: Sho KAWAKAMI, Kyoto (JP); Yasufumi TOYODA, Kyoto (JP)

(73) Assignee: ROHM CO., LTD., Kyoto (JP)

(21) Appl. No.: 18/806,480

(22) Filed: Aug. 15, 2024

(30) Foreign Application Priority Data
Aug. 23, 2023 (JP) 2023-135682

(51) Int. Cl. H10N 52/00; H10N 52/01

(52) U.S. Cl. CPC H10N 52/101; H10N 52/01

(57) ABSTRACT

The present disclosure provides a Hall element. The Hall element includes: a substrate; a magnetosensitive layer, disposed on a top surface of the substrate; a protective layer, covering the magnetosensitive layer and having an opening exposing a predetermined region of the magnetosensitive layer; an ohmic contact layer, electrically connected to the magnetosensitive layer exposed from the opening, wherein a portion of the ohmic contact layer is in contact with the protective layer around the opening; and a metal layer, disposed on the ohmic contact layer, wherein a portion of the metal layer is in contact with the protective layer around the ohmic contact layer.

### TECHNICAL FIELD

The present disclosure relates to a Hall element and a manufacturing method thereof, and a semiconductor device.

### BACKGROUND

A Hall element is an element that converts a magnetic signal into an electrical signal and performs detection, and is extensively applied in fields such as current sensors and rotation angle detection sensors of motors. In the configuration of a current Hall element, for example, patent document 1 discloses a Hall element in which a magnetosensitive layer includes an n-type semiconductor formed by adding Si (silicon) as an impurity to gallium arsenide (GaAs). The Hall element is disposed on a substrate to have the magnetosensitive layer appearing as a cross shape in a plan view. Electrodes are disposed in electrical connection on surfaces of individual ends of the cross-shaped magnetosensitive layer, and surfaces of the magnetosensitive layer not disposed with electrodes are covered by a protective layer such as a silicon nitride (SiN).

### PRIOR ART DOCUMENT

### Patent Publication

[Patent document 1] Japan Patent Publication No. 2017-50394

### BRIEF DESCRIPTION OF THE DRAWINGS

FIG. 1 is a plan view of a Hall element.

FIG. 2 is a cross-sectional diagram of a Hall element.

FIG. 3 is a cross-sectional diagram of a main part of a Hall element.

FIG. 4 is an enlarged cross-sectional diagram of a Hall element.

FIG. 5 is a flowchart of a manufacturing method of a Hall element.

FIG. 6 is a flowchart of a manufacturing method of a Hall element.

FIG. 7 is a flowchart of a manufacturing method of a Hall element.

FIG. 8 is a flowchart of a manufacturing method of a Hall element.

FIG. 9 is a flowchart of a manufacturing method of a Hall element.

FIG. 10 is a flowchart of a manufacturing method of a Hall element.

FIG. 11 is a flowchart of a manufacturing method of a Hall element.

FIG. 12 is a flowchart of a manufacturing method of a Hall element.

FIG. 13 is a flowchart of a manufacturing method of a Hall element.

FIG. 14 is a flowchart of a manufacturing method of a Hall element.

### DETAILED DESCRIPTION OF THE EMBODIMENTS

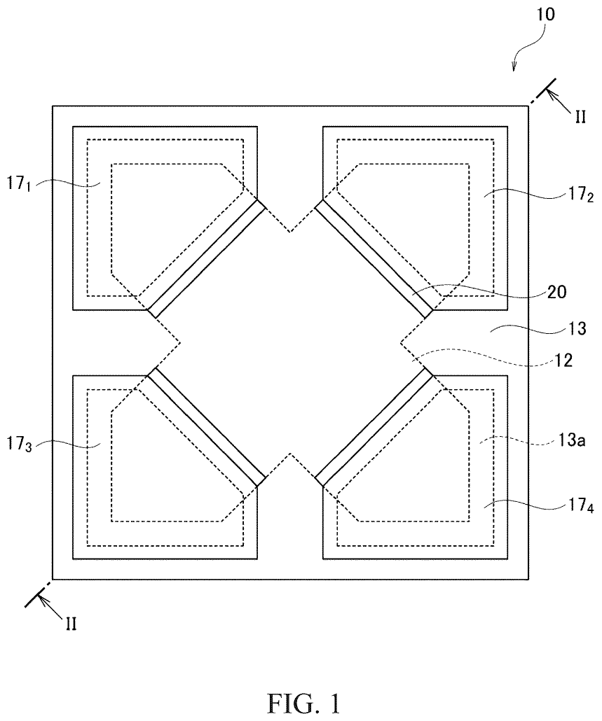

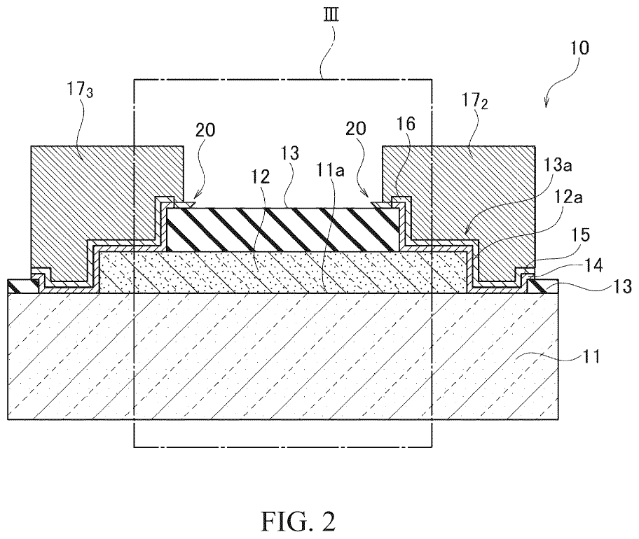

Details of the embodiments of a Hall element and a manufacturing method thereof and a semiconductor device are described with reference to the accompanying drawings below. FIG. 1 shows a plan view of a Hall element 10 according to the present embodiment. FIG. 2 shows a cross-sectional diagram of dissecting the Hall element 10 along the section line II-II in FIG. 1.

In the Hall element 10, a magnetosensitive layer 12 is disposed to form a cross shape extending in two diagonal directions in a substantially rectangular shape in a plan view on a top surface 11a of a substrate 11 in a substantially rectangular shape in the plan view. A protective layer 13 is formed to cover the top surface 11a of the substrate 11 disposed with the magnetosensitive layer 12. In the protective layer 13, an opening 13a is formed to expose a predetermined region including an end of the magnetosensitive layer 12 in a cross shape and a portion of the top surface 11a of the substrate 11 adjacent to the end.

Moreover, in the Hall element 10, an electrode 17 electrically connected to the end of the magnetosensitive layer 12 is disposed to cover the opening 13a of the protective layer 13. In a region on a bottom surface of the electrode 17 and exposed from the opening 13a of the protective layer 13, that is, the predetermined region including the end of the magnetosensitive layer 12 and a portion of the top surface 11a of the substrate 11 adjacent to the end, an ohmic contact layer 14 forming a eutectic crystal with the magnetosensitive layer 12, a first metal layer 15 preventing ball-up of the ohmic contact layer 14 and a second metal layer 16 forming a base for plating are sequentially laminated and interposed to electrically connect the magnetosensitive layer 12 with the electrode 17.

Referring to FIG. 1, the electrode 17 is formed by four electrodes including first electrode 17₁ to fourth electrode 17₄. Among these electrodes, for example, the first electrode 17₁ and the fourth electrode 17₄ opposite to each other in one diagonal direction form input terminals, and for example, the second electrode 17₂ and the third electrode 17₃ opposite to each other in the other diagonal direction form output terminals. In the magnetosensitive layer 12, carriers moving on a path between a pair of input terminals including the first electrode 17₁ and the fourth electrode 17₄ exert a Lorentz force in a direction orthogonal to a moving direction via a magnetic field that penetrates the magnetosensitive layer 12, and an electromotive force corresponding to a strength of the magnetic field is detected in the output terminals including the second electrode 17₂ and the third electrode 17₃ that are opposite in a direction substantially orthogonal to the moving direction.

In the Hall element 10, the substrate 11 includes gallium arsenide (GaAs) as a III-V group compound semiconductor. The magnetosensitive layer 12 includes an n-type compound semiconductor of GaAs which is doped with at least one of silicon (Si) and tellurium (Te) as an impurity. In order to ensure the sensitivity for detecting magnetism, the magnetosensitive layer 12 is doped with an impurity at a low concentration so as to increase the mobility of carriers.

The protective layer 13 includes silicon nitride (SiN). Apart from the region where the opening 13a is formed, the protective layer 13 covers the top surface 11a of the substrate 11 and the magnetosensitive layer 12 to protect the top surface 11a of the substrate 11 and the magnetosensitive layer 12. In the electrode 17, the four electrodes including the first electrode 17₁ to the fourth electrode 17₄ are respectively electrically connected to four ends of the magnetosensitive layer 12, and provide the Hall element 10 with a connection path to an exterior.

The ohmic contact layer 14 includes an alloy of gold germanium nickel (AuGeNi), and forms a eutectic crystal with the magnetosensitive layer 12 to ensure a stable ohmic contact with the magnetosensitive layer 12. The first metal layer 15 is formed of titanium (Ti), and prevents deterioration of conductivity due to such as ball-up of alloy components constituting the first metal layer 15. The second metal layer 16 includes gold (Au), and forms a base layer of a gold-plated layer. The electrode 17 includes the gold-plated layer formed by using the second metal layer 16 as a base layer for plating so as to cover the opening 13a of the protective layer 13.

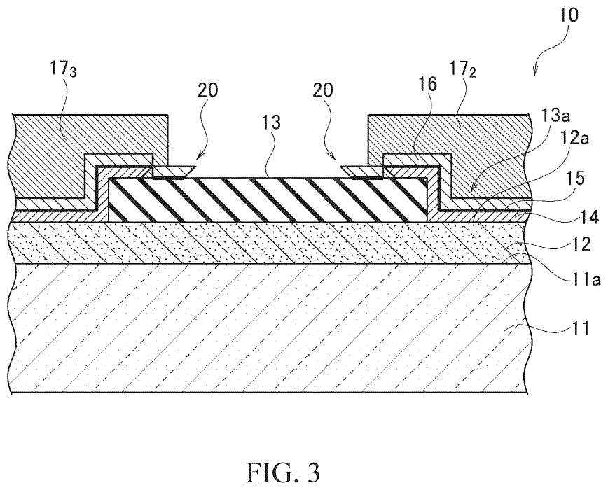

FIG. 3 shows a cross-sectional diagram of a main part of the Hall element 10, and is equivalent to the region III in the cross-sectional diagram in FIG. 2. Apart from that formed in the opening 13a of the protective layer 13, a surface of the magnetosensitive layer 12 is covered by the protective layer 13. The opening 13a of the protective layer 13 is formed in a region including the end of the magnetosensitive layer 12, and is covered by the electrode 17. A laminate formed by sequentially laminating the ohmic contact layer 14, the first metal layer 15 and the second metal layer 16 is placed between a surface of the end of the magnetosensitive layer 12 and a bottom surface of the electrode 17. The laminate, from within the opening 13a, is in contact with and extends from the protective layer 13 formed on a top surface of the magnetosensitive layer 12, and is in contact with an island portion 20 formed by laminating the first metal layer 15 and the second metal layer 16 formed directly below a side surface of the electrode 17 on the surface of the protective layer 13.

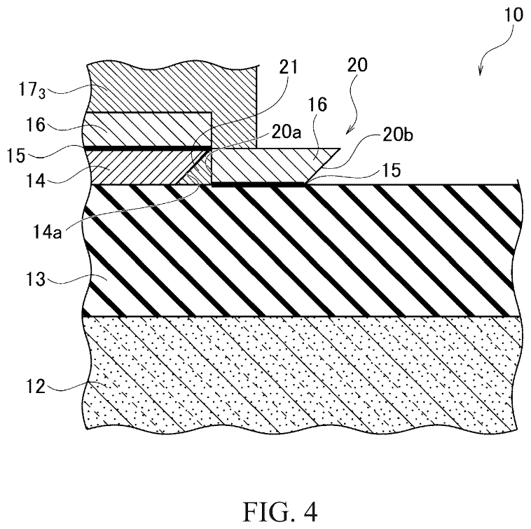

FIG. 4 shows an enlarged cross-sectional diagram of the proximity of the island portion 20 in the Hall element 10. On the surface of the protective layer 13, the island portion 20 formed by laminating the first metal layer 15 and the second metal layer 16 directly below the side surface of the electrode 17. A portion including a root portion of the island portion 20 is located closer to an inside than the side surface of the electrode 17, and the remaining portion of the island portion 20 protrudes from the side surface of the electrode 17. An end face 20b of the island portion 20 protruding from the side surface of the electrode 17 has an eaves-like shape that protrudes further forward as a height from the surface of the protective layer 13 increases.

The island portion 20 is formed to be in contact with a body portion formed by laminating the first metal layer 15 and the second metal layer 16 on the ohmic contact layer 14 in the electrode 17. More specifically, the root portion of the island portion 20 located on the side surface of the electrode 17 is formed to face and be in contact with an end of the laminate of the ohmic contact layer 14, the first metal layer 15 and the second metal layer 16 formed on the surface of the protective layer 13. An end face 14a of the ohmic contact layer 14 facing the root portion of the island portion 20 has an eaves-like shape that protrudes further forward as the height from the surface of the protective layer 13 increases. The gold-plated layer forming the electrode 17 fills a gap formed by the eaves-like end face 14a of the ohmic contact layer 14, the end face 20a of the root portion of the island portion 20 and the surface of the protective layer 13, thereby forming a metal-filling portion 21.

In the Hall element 10, the island portion 20 is formed at an interface between the surface of the protective layer 13 formed on the surface of the magnetosensitive layer 12 and the side surface of the electrode 17. The island portion 20 seals the interface between the ohmic contact layer 14 and the protective layer 13, preventing moisture penetration from the interface between the ohmic contact layer 14 and the protective layer 13. Since Ti forming the first metal layer 15 of the island portion 20 has a property of high adhesion to SiN forming the protective layer 13, the island portion 20 and the protective layer 13 can be reliably sealed.

Moreover, the metal-filling portion 21 with gold plating is formed in the gap between the island portion 20 and the ohmic contact layer 14. The metal-filling portion 21 is in contact with the interface between the ohmic contact layer 14 and the protective layer 13, and seals the interface between the ohmic contact layer 14 and the protective layer 13. Thus, even if the island portion 20 is unable to prevent moisture penetration, sealing can be achieved by the metal-filling portion 21, accordingly reliably preventing moisture penetration from the interface between the ohmic contact layer 14 and the protective layer 13.

In addition, in the Hall element 10, the substrate 11 and the magnetosensitive layer 12 include GaAs of the III-V group; however, the present disclosure is not limited to the example above. For example, other types of compound semiconductors such as indium antimonide (InSb) and indium arsenide (InAs) can also be used.

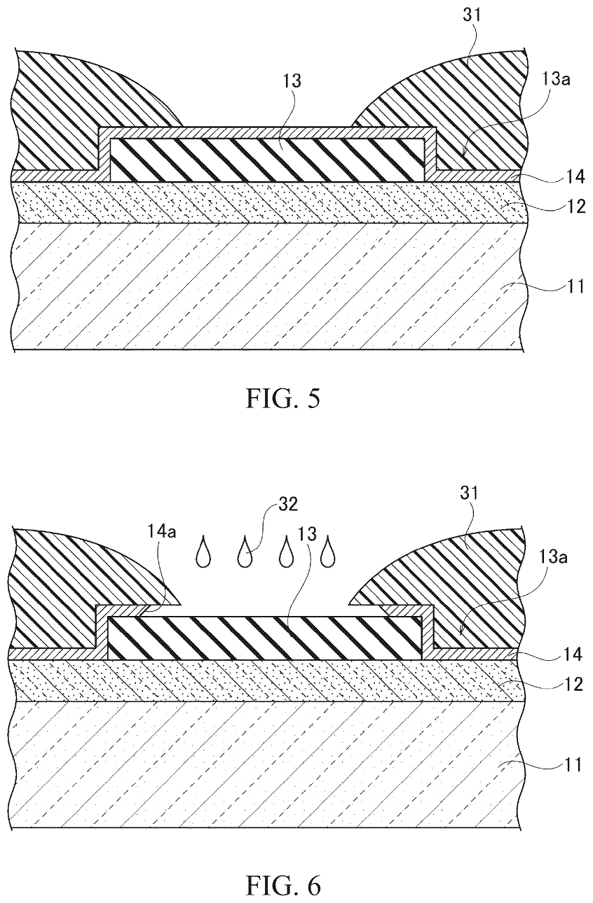

Next, details of a manufacturing method of the Hall element 10 are described with reference to flowcharts in FIG. 5 to FIG. 14 below. Similar to FIG. 3, FIG. 5 to FIG. 14 represent the main part of the Hall element 10 as the region III shown in FIG. 2.

As shown in FIG. 5, the magnetosensitive layer 12 is formed on the top surface 11a of the substrate 11 containing GaAs, wherein the magnetosensitive layer 12 includes an n-type compound semiconductor of GaAs which is doped with at least one of Si and Te as an impurity. As described above, in the plan view, the magnetosensitive layer 12 is formed to have a cross shape extending in two diagonal directions of the top surface 11a of the substrate 11 in a substantially rectangular shape in the plan view. Next, the protective layer 13 including SiN is formed to cover the top surface 11a of the substrate 11 disposed with the magnetosensitive layer 12. In the protective layer 13, the opening 13a is formed to expose a predetermined region including the end of the magnetosensitive layer 12 and a portion of the top surface 11a of the substrate 11 adjacent to the end.

On the top surface 11a of the substrate 11 where the protective layer 13 is formed, the ohmic contact layer 14 including an alloy of AuGeNi is formed to cover the protective layer 13. Further, on the surface of the ohmic contact layer 14, a first mask 31 containing resin is formed in a predetermined pattern to cover a predetermined region such as the opening 13a formed in the protective layer 13 and its surroundings.

As shown in FIG. 6, the ohmic contact layer 14 having the first mask 31 formed on the surface in FIG. 5 is etched by using a first etching solution 32. The ohmic contact layer 14 is formed such that a predetermined region, such as the opening 13a formed in the protective layer 13 and a periphery of the opening 13a, are covered with the first mask 31. Thus, a region of the ohmic contact layer 14 not covered by the first mask 31 and thus exposed is etched by the first etching solution 32 and removed.

Moreover, the ohmic contact layer 14 covered by the first mask 31 in an end of the protective layer 13 is also etched by the first etching solution 32 penetrating between the surface of the protective layer 13 and the first mask 31, from the end of the first mask 31 to a predetermined depth and is thus removed. Herein, the protective layer 13 containing SiN has a higher affinity with respect to the first etching solution 32 than the first mask 31 containing resin, and a speed of etching of the ohmic contact layer 14 increases as a distance gets farther away from the first mask 31 and closer to the protective layer 13. Thus, the end face 14a of the ohmic contact layer 14 placed between the protective layer 13 and the first mask 31 is formed to have an eaves-like shape protruding further forward as a height from the protective layer 13 to the first mask 31 increases.

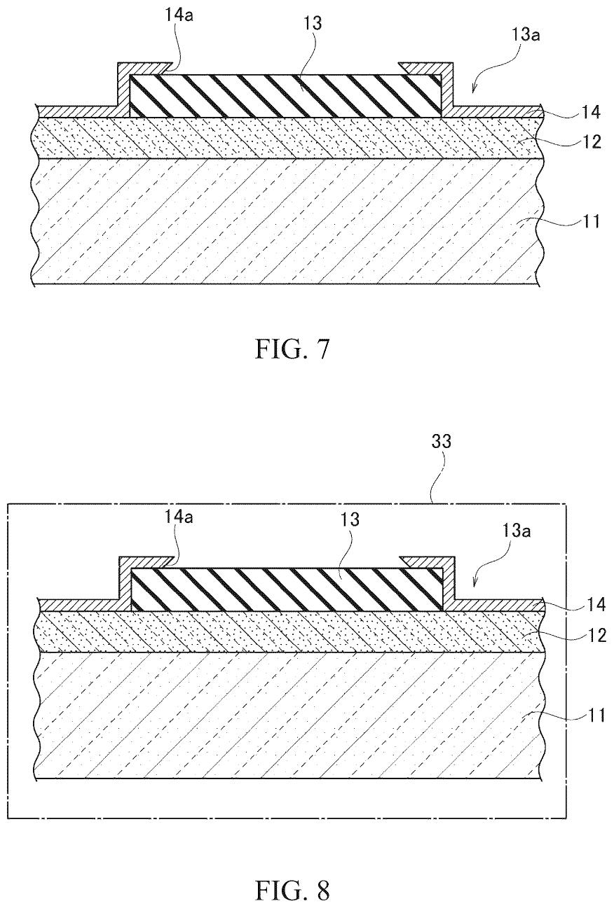

As shown in FIG. 7, the first mask 31 is removed after the ohmic contact layer 14 is etched in FIG. 6. The end of the protective layer 13 formed on the surface of the magnetosensitive layer 12 and the opening 13a of the protective layer 13 are covered by the ohmic contact layer 14. The end face 14a of the ohmic contact layer 14 covering the end of the protective layer 13 is formed to have an eaves-like shape protruding further forward as the height from the protective layer 13 increases.

As shown in FIG. 8, by heating in a heating furnace, a eutectic crystal is formed between the magnetosensitive layer 12 and the ohmic contact layer 14 containing an alloy of AuGeNi in contact with the magnetosensitive layer 12 in the opening 13a of the protective layer 13. The numeral 33 in the drawing represents a high-temperature environment in a heating furnace.

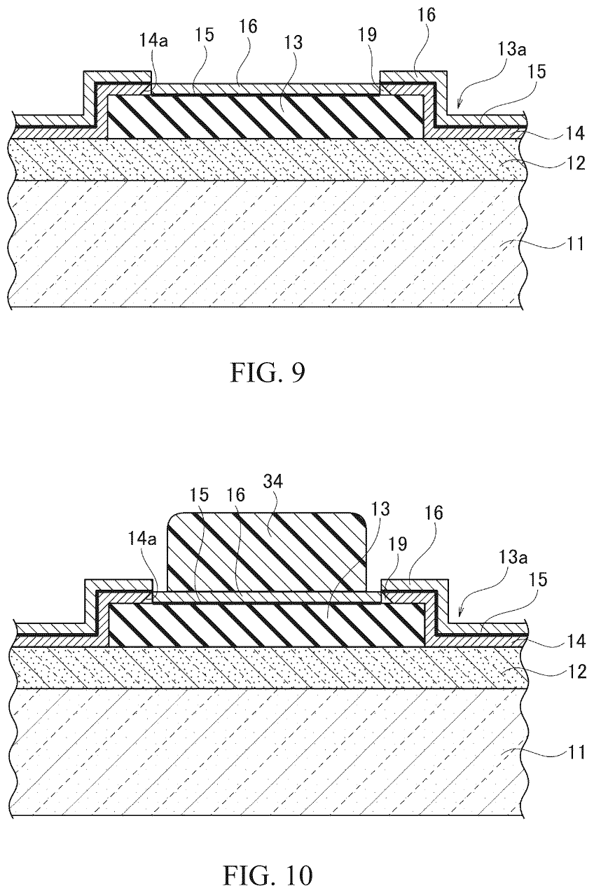

As shown in FIG. 9, after the eutectic crystal is formed between the magnetosensitive layer 12 and the ohmic contact layer 14 in FIG. 8, a laminate of the first metal layer 15 containing Ti for preventing ball-up of the ohmic contact layer 14 and the second metal layer 16 containing Au as a base layer of a gold-plated layer is formed. Since the end of the protective layer 13 and the opening 13a of the protective layer 13 formed on the surface of the magnetosensitive layer 12 are covered by the ohmic contact layer 14, by forming the first metal layer 15 and the second metal layer 16 on the surface of the ohmic contact layer 14, a laminate formed by sequentially laminating the ohmic contact layer 14, the first metal layer 15 and the second metal layer 16 is formed. In the protective layer 13, apart from a region at the end that is not covered by the ohmic contact layer 14, the first metal layer 15 and the second metal layer 16 are directly laminated and formed on the surface of the protective layer 13. Directly below the eaves-shaped end face 14a of the ohmic contact layer 14 formed at the end of the protective layer 13 and on the surface of the protective layer 13, a gap 19 having a triangular cross section is formed to be in contact with end faces of the first metal layer 15 and the second metal layer 16 directly formed on the surface of the protective layer 13.

As shown in FIG. 10, the first metal layer 15 and a surface of the second metal layer 16 formed on the surface of the protective layer 13 in FIG. 9, a second mask 34 containing resin is formed to have a predetermined height to be at a predetermined interval from the laminate formed by the ohmic contact layer 14, the first metal layer 15 and the second metal layer 16 formed at the end of the protective layer 13.

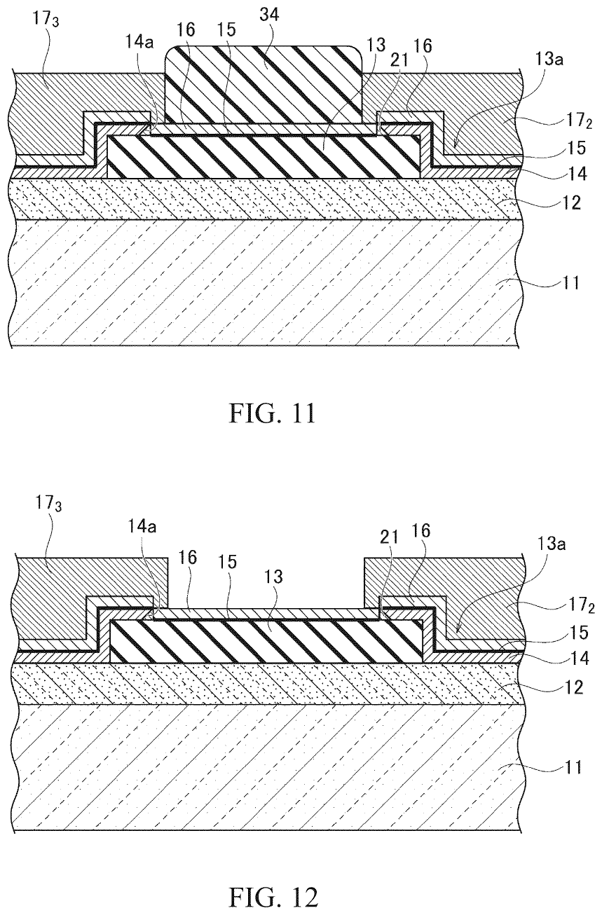

As shown in FIG. 11, in a region from the ohmic contact layer 14 covering the end of the protective layer 13 and the opening 13a of the protective layer 13, the surface of the laminate of the first metal layer 15 and the second metal layer 16 in FIG. 10 to the first metal layer 15 and the surface of the second metal layer 16 formed on the surface of the magnetosensitive layer 12 and not formed with the second mask 34, the electrode 17 is continuously formed by means of gold plating to cover the second metal layer 16 forming the base layer for plating. When the electrode 17 is continuously formed by means of gold plating, the gap 19 formed directly below the eaves-like end face 14a of the ohmic contact layer 14 on the surface of the protective layer 13 is also filled with gold plating, thereby forming the metal-filling portion 21. The electrode 17 in FIG. 11 forms the third electrode 17₃ and the second electrode 17₂ in FIG. 1.

In FIG. 12, the second mask 34 is removed after the electrode 17 is formed by means of gold plating in FIG. 11. By removing the second mask 34, the laminate of the first metal layer 15 and the second metal layer 16 covered by the second mask 34 and the side surface of the electrode 17 are exposed.

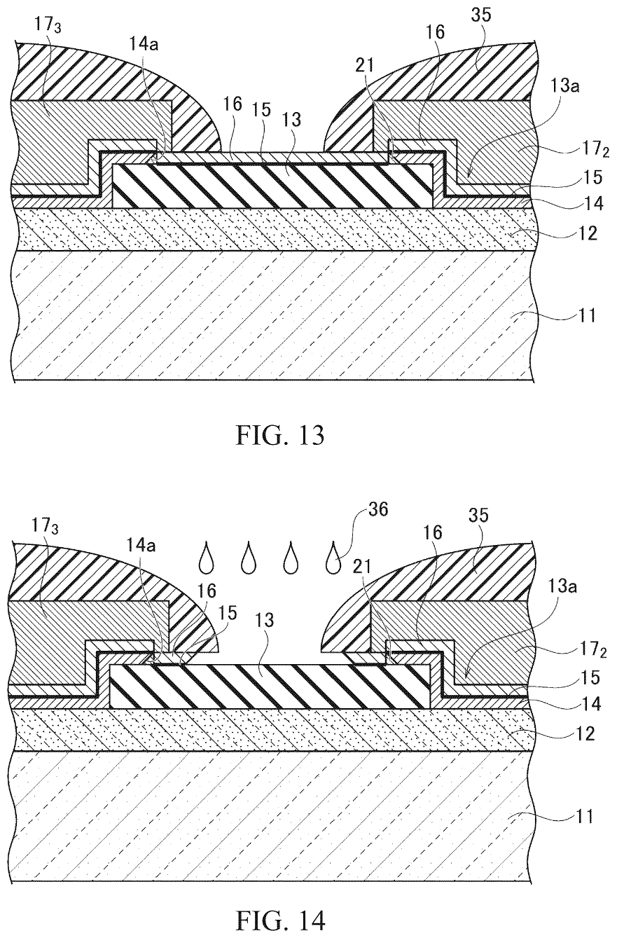

As shown in FIG. 13, after the second mask 34 is removed in FIG. 12, a third mask 35 containing resin is formed to cover the electrode 17 and a predetermined range of the laminate of the first metal layer 15 and the second metal layer 16 adjacent to the side surface of the electrode 17. A region at a center of the laminate of the first metal layer 15 and the second metal layer 16 covering the protective layer 13 is not covered by the second mask 34 and is exposed.

As shown in FIG. 14, after the third mask 35 is formed on the electrode 17 and in the region adjacent to the electrode 17 in FIG. 13, the region at the center of the laminate of the first metal layer 15 and the second metal layer 16 exposed from the third mask 35 is removed by etching with a second etching solution 36.

Moreover, the laminate of the first metal layer 15 and the second metal layer 16 covered by the third mask 35 at the end of the protective layer 13 is also etched by the second etching solution 36 penetrating between the protective layer 13 and the third mask 35, from the end of the third mask 35 to a predetermined depth and is thus removed. Herein, the protective layer 13 containing SiN has a higher affinity with respect to the second etching solution 36 than the third mask 35 containing resin, and a speed of etching of the laminate of the first metal layer 15 and the second metal layer 16 increases as a distance gets farther away from the third mask 35 and closer to the protective layer 13. Thus, an end face of the laminate of the first metal layer 15 and the second metal layer 16 placed between the protective layer 13 and the third mask 35 is formed to have an eaves-like shape protruding further forward as a height from the protective layer 13 to the third mask 35 increases.

Referring to FIG. 3 and FIG. 4, if the third mask 35 is removed in FIG. 14, in the Hall element 10, the island portion 20 formed by laminating the first metal layer 15 and the second metal layer 16 is formed directly below the side surface of the electrode 17 formed on the surface of the protective layer 13 on the surface of the magnetosensitive layer 12. A portion including a root portion of the island portion 20 is located closer to an inside than the side surface of the electrode 17, and the remaining portion of the island portion 20 protrudes from the side surface of the electrode 17. The end face 20b of the island portion 20 protruding from the side surface of the electrode 17 has an eaves-like shape that protrudes further forward as a height from the surface of the protective layer 13 increases.

The island portion 20 is formed to be in contact with a body portion formed by laminating the first metal layer 15 and the second metal layer 16 on the ohmic contact layer 14 in the electrode 17. More specifically, the root portion of the island portion 20 located on the side surface of the electrode 17 is formed to face and be in contact with an end of the laminate of the ohmic contact layer 14, the first metal layer 15 and the second metal layer 16 formed on the surface of the protective layer 13. An end face 14a of the ohmic contact layer 14 facing the root portion of the island portion 20 has an eaves-like shape that protrudes further forward as the height from the surface of the protective layer 13 increases. The gold-plated layer forming the electrode 17 fills a gap formed by the eaves-like end face 14a of the ohmic contact layer 14, the end face 20a of the root portion of the island portion 20 and the surface of the protective layer 13, thereby forming the metal-filling portion 21.

With a series of steps above, the Hall element 10 can be manufactured. In the manufacturing method of the Hall element, according to normal manufacturing steps, the island portion 20 formed by laminating the first metal layer 15 and the second metal layer 16 can be formed directly below the side surface of the electrode 17 formed on the surface of the protective layer 13 on the surface of the magnetosensitive layer 12, further forming the gold-plated metal-filling portion 21 in the gap between the ohmic contact layer 14 and the island portion 20. With the island portion 20 and the metal-filling portion 21 formed by such means, moisture penetration from the interface between the protective layer 13 and the ohmic contact layer 14 can be reliably prevented.

Moreover, the Hall element 10 is described as an example in this embodiment; however, the present disclosure is not limited to the example above. Instead of the Hall element 10, in any semiconductor device in need of preventing moisture penetration from an interface between an ohmic contact layer and a protective layer, moisture penetration can be prevented by forming the island portion 20 and the metal-filling portion 21 and sealing the interface in a manner similar to the Hall element 10. In the semiconductor device, in substitution for the magnetosensitive layer 12 in the Hall element 10, generally by protecting an active layer from moisture penetration, deterioration of the active layer caused by such moisture penetration can be prevented.

### (Note 1)

A Hall element 10, including:
a substrate 11;
a magnetosensitive layer 12, disposed on a top surface 11a of the substrate 11;
a protective layer 13, covering the magnetosensitive layer 12 and having an opening 13a exposing a predetermined region of the magnetosensitive layer 12;
an ohmic contact layer 14, electrically connected to the magnetosensitive layer 12 exposed from the opening 13a, wherein a portion of the ohmic contact layer 14 is in contact with the protective layer 13 around a periphery of the opening 13a; and
a first metal layer 15, disposed on the ohmic contact layer 14, wherein a portion of the first metal layer 15 is in contact with the protective layer 13 around a periphery of the ohmic contact layer 14.

Since the first metal layer 15 is in contact with the protective layer 13 around the periphery of the ohmic contact layer 14, it is possible to prevent moisture from entering the interface between the ohmic contact layer 14 and the protective layer 13.

### (Note 2)

In the Hall element 10 of Note 1, the first metal layer 15 includes a body portion disposed on the ohmic contact layer 14 and an island portion 20 in contact with the protective layer 13 around the ohmic contact layer 14. The island portion 20 can seal the interface between the ohmic contact layer 14 and the protective layer 13 to prevent the intrusion of moisture.

### (Note 3)

The Hall element 10 of Note 2 further includes an electrode 17 made of a plated layer disposed on the first metal layer 15, and forms a metal-filling portion 21 in which a metal of the plated layer fills a gap 19 between the ohmic contact layer 14 and an end face 20a of the island portion 20 facing the ohmic contact layer 14. The metal-filling portion 21 further seals the interface between the ohmic contact layer 14 and the protective layer 13 to prevent the intrusion of moisture.

### (Note 4)

In the Hall element 10 of Note 3, the electrode 17 made of the plated layer is continuously disposed from the body portion to the island portion 20 of the first metal layer 15. The electrode made of the continuously formed plated layer allows the metal of the plated layer to fill the gap between the ohmic contact layer 14 and the island portion 20.

### (Note 5)

In the Hall element 10 of any one of Notes 1 to 4, the magnetosensitive layer 12 includes a III-V group compound semiconductor. For example, by using a semiconductor such as GaAs, the sensitivity of the Hall element 10 can be ensured.

### (Note 6)

In the Hall element 10 of any one of Notes 1 to 5, the ohmic contact layer 14 is made of an alloy that forms a eutectic crystal with the magnetosensitive layer 12. By forming the eutectic crystal, a stable ohmic contact can be ensured.

### (Note 7)

In the Hall element 10 of any one of Notes 1 to 6, the first metal layer 15 is intended to prevent ball-up of the ohmic contact layer 14, and is laminated with a second metal layer 16 for forming a base of the electrode 17, which is to be the plated layer. By preventing ball-up of the alloy constituting the ohmic contact layer 14, stable electrical conduction can be maintained, and by providing a base for the plating layer, stable growth of the plating layer can be ensured.

### (Note 8)

A method of manufacturing a Hall element 10, comprising:
forming a magnetosensitive layer 12 on a top surface 11a of a substrate 11;
forming a protective layer 13 to cover the top surface 11a on which the magnetosensitive layer 12 is formed, such that a predetermined region of the magnetosensitive layer 12 is exposed through an opening 13a;
forming an ohmic contact layer 14 electrically connected to the magnetosensitive layer 12 exposed from the opening 13a, wherein a portion of the ohmic contact layer is in contact with the protective layer 13 around a periphery of the opening 13a; and
forming a first metal layer 15 on the ohmic contact layer 14, wherein a portion of the first metal layer 15 is in contact with the protective layer 13 around a periphery of the ohmic contact layer 14.

Since the first metal layer 15 is in contact with the protective layer 13 around the periphery of the ohmic contact layer 14, it is possible to prevent moisture from entering the interface between the ohmic contact layer 14 and the protective layer 13.

### (Note 9)

In the method for manufacturing the Hall element 10 of Note 8, the forming of the first metal layer 15 includes: forming a body portion on the ohmic contact layer 14; and forming an island portion 20 in contact with the protective layer 13 around the ohmic contact layer 14. The island portion 20 can seal the interface between the ohmic contact layer 14 and the protective layer 13 to prevent the intrusion of moisture.

### (Note 10)

The method for manufacturing the Hall element 10 of Note 9 further includes forming an electrode 17 of a plated layer on the first metal layer 15. The forming of the electrode 17 of the plated layer is performed by filling a gap 19 between the ohmic contact layer 14 and an end surface 20a of the island portion 20 facing the ohmic contact layer 14 by a metal of the plated layer to form a metal-filling portion 21. The metal-filling portion 21 further seals the interface between the ohmic contact layer 14 and the protective layer 13 to prevent the intrusion of moisture.

### (Note 11)

In the method for manufacturing the Hall element 10 of Note 9, the electrode 17 of the plated layer is continuously formed from the body portion to the island portion 20 of the first metal layer 15. The electrode made of the continuously formed plating layer allows the metal of the plated layer to fill the gap between the ohmic contact layer 14 and the island portion 20.

### (Note 12)

A semiconductor device, comprising:
a substrate 11;
an active layer, disposed on a top surface 11a of the substrate 11;
a protective layer 13, covering the active layer and having an opening 13a exposing a predetermined region of the active layer;
an ohmic contact layer 14, electrically connected to the active layer exposed through the opening 13a, wherein a portion of the ohmic contact layer 14 is disposed on the protective layer 13 around the opening 13a; and
a first metal layer 15, disposed on the ohmic contact layer 14, wherein a portion of the first metal layer 15 is in contact with the protective layer 13 around the ohmic contact layer 14.

Since the first metal layer 15 is in contact with the protective layer 13 around a periphery of the ohmic contact layer 14, it is possible to prevent moisture from entering the interface between the ohmic contact layer 14 and the protective layer 13.

1. A Hall element, comprising:
a substrate;
a magnetosensitive layer, disposed on a top surface of the substrate;
a protective layer, covering the magnetosensitive layer and having an opening exposing a predetermined region of the magnetosensitive layer;
an ohmic contact layer, electrically connected to the magnetosensitive layer exposed from the opening, wherein a portion of the ohmic contact layer is in contact with the protective layer around a periphery of the opening; and
a metal layer, disposed on the ohmic contact layer, wherein a portion of the metal layer is in contact with the protective layer around a periphery of the ohmic contact layer.

2. The Hall element of claim 1, wherein the metal layer includes:
a body portion, disposed on the ohmic contact layer; and
an island portion, in contact with the protective layer around the ohmic contact layer.

3. The Hall element of claim 2, further comprising a plated layer disposed on the metal layer, wherein a metal of the plated layer fills a gap between the ohmic contact layer and an end face of the island portion facing the ohmic contact layer.

4. The Hall element of claim 3, wherein the plated layer is continuously disposed from the body portion to the island portion of the metal layer.

5. The Hall element of claim 3, wherein the magnetosensitive layer includes a III-V group compound semiconductor.

6. The Hall element of claim 5, wherein the ohmic contact layer is formed by an alloy forming a eutectic crystal with the magnetosensitive layer.

7. The Hall element of claim 6, wherein the metal layer is a laminate of:
a first metal layer for preventing ball-up of the ohmic contact layer; and
a second metal layer for forming a base of the plated layer.

8. A method of manufacturing a Hall element, comprising:
forming a magnetosensitive layer on a top surface of a substrate;
forming a protective layer to cover the top surface on which the magnetosensitive layer is formed, such that a predetermined region of the magnetosensitive layer is exposed through an opening;
forming an ohmic contact layer electrically connected to the magnetosensitive layer exposed from the opening, wherein a portion of the ohmic contact layer is in contact with the protective layer around a periphery of the opening; and
forming a metal layer on the ohmic contact layer, wherein a portion of the metal layer is in contact with the protective layer around a periphery of the ohmic contact layer.

9. The method of claim 8, wherein the forming of the metal layer includes:
forming a body portion on the ohmic contact layer; and
forming an island portion in contact with the protective layer around the ohmic contact layer.

10. The method of claim 9, further comprising forming a plated layer on the metal layer, wherein the forming of the plated layer includes filling a gap between the ohmic contact layer and an end surface of the island portion facing the ohmic contact layer by a metal of the plated layer.

11. The method of claim 10, wherein the plated layer is continuously formed from the body portion to the island portion of the metal layer.

12. A semiconductor device, comprising:
a substrate;
an active layer, disposed on a top surface of the substrate;
a protective layer, covering the active layer and having an opening exposing a predetermined region of the active layer,
an ohmic contact layer, electrically connected to the active layer exposed through the opening, wherein a portion of the ohmic contact layer is disposed on the protective layer around the opening; and
a metal layer, disposed on the ohmic contact layer, wherein a portion of the metal layer is in contact with the protective layer around the ohmic contact layer.
